(19) United States
(12) Patent Application Publication
(10) Pub. No.: US 2026/0361170 A1
(43) Pub. Date: Nov. 12, 2026

(54) Printed Circuit Board Stators With Filter Inductors

(71) Applicant: Hayward Industries, Inc., Charlotte, NC (US)

(72) Inventor: Maxwell S. DeHaven, Warwick, RI (US)

(73) Assignee: Hayward Industries, Inc., Charlotte, NC (US)

(21) Appl. No.: 19/669,314

(22) Filed: May 6, 2026

Related U.S. Application Data
(60) Provisional application No. 63/803,105, filed on May 9, 2025.

(51) Int. Cl. H02K 3/26; H02K 7/00; H02K 11/02; H02K 11/33; H05K 1/02; H05K 1/16; H05K 1/181

(52) U.S. Cl. CPC H02K 3/26; H02K 7/003; H02K 11/02; H02K 11/33; H05K 1/0233; H05K 1/165; H05K 1/181; H02K 2211/03; H05K 2201/086; H05K 2201/1009

(57) ABSTRACT

An improved PCB stator with filter inductors is provided. The PCB stator includes a PCB, a plurality of stator coils formed in the PCB, and a plurality of filter inductors in electrical communication with the plurality of stator coils. The plurality of filter inductors are positioned circumferentially about a shaft aperture formed in the PCB and extend radially outwardly from the shaft aperture, and the plurality of stator coils are positioned circumferentially about and extend radially outwardly from the plurality of filter inductors. The filter inductors could be planar and generally arcuate in shape, and each filter inductor can include a filter coil formed in the PCB and first and second magnetic components positioned proximal to the filter coil and on opposite surfaces of the PCB.

### RELATED APPLICATIONS

The present application claims the benefit of U.S. Provisional Application Ser. No. 63/803,105 filed on May 9, 2025, the entire disclosure of which is expressly incorporated herein by reference.

### BACKGROUND

### Technical Field

The present disclosure relates generally to the field of motor stators. More specifically, the present disclosure relates to printed circuit board stators with filter inductors.

### Related Art

Stators are components of electric motors which produce a rotating magnetic field using coils supplied with electricity. The magnetic field generated by the coils of the stator causes a rotor in proximity to the stator to rotate, thereby providing mechanical motion. One type of known stator is a printed circuit board (PCB) stator, which can be fabricated from multi-layer PCBs with layers of copper that are stacked together and interconnected to create the coils utilized to generate the magnetic field.

An example of a known PCB stator is shown in FIG. 1 and indicated generally at 10. The stator 10 is fabricated from a multi-layer PCB 20 and includes a plurality of coils 30 that are formed from interconnected copper traces formed on the layers of the multi-layer PCB 20. The coils 30 generate a rotating magnetic field which causes a corresponding rotor to rotate. As can be seen, the stator 10 includes a central aperture 40 that extends through the stator 10, and the coils 30 extend radially about the central aperture 40. One drawback of such an arrangement, however, is that the central aperture 40 represents wasted or “dead” space.

Motors which utilize PCB stators are often driven by variable frequency drives (VFDs). VFDs are motor controllers that drive an electric motor by controlling phase current through varying the frequency and/or voltage supplied to the coils of the PCB stator, in order to allow for speed control of the motor. Often, such VFDs utilize pulse width modulation (PWM) circuitry to vary the frequency and/or voltage, which require the use of filter inductors in order filter or “smooth” the drive signal generated by the VFD. The filter inductors take up space on the circuit board(s) of the VFD, thereby increasing the size and bulkiness of the VFD.

Accordingly, what would be desirable, but have not yet been provided, are printed circuit board stators with filter inductors which address the foregoing and other needs.

### SUMMARY

The present disclosure relates to an improved PCB stator with filter inductors. The PCB stator includes a PCB, a plurality of stator coils formed in the PCB, and a plurality of filter inductors in electrical communication with the plurality of stator coils. The plurality of filter inductors are positioned circumferentially about a shaft aperture formed in the PCB and extend radially outwardly from the shaft aperture, and the plurality of stator coils are positioned circumferentially about and extend radially outwardly from the plurality of filter inductors. The filter inductors could be planar and generally arcuate in shape, and each filter inductor can include a filter coil formed in the PCB and first and second magnetic components positioned proximal to the filter coil and on opposite surfaces of the PCB.

### BRIEF DESCRIPTION OF THE DRAWINGS

The foregoing features of the invention will be apparent from the following Detailed Description of the Invention, taken in connection with the accompanying drawings, in which:

FIG. 1 is a diagram illustrating a prior art PCB stator;

FIG. 2 is a diagram illustrating a PCB stator in accordance with the present disclosure;

FIG. 3 is a side view of the PCB stator of FIG. 2;

FIG. 4 is an exploded partial perspective view of the PCB stator of FIG. 2;

FIG. 5 is a side view of the PCB stator of the present disclosure configured for operation with two planar rotors and an associated rotor shaft; and

FIG. 6 is a diagram illustrating implementation of the PCB stator of the present disclosure in a motor and a pump.

### DETAILED DESCRIPTION

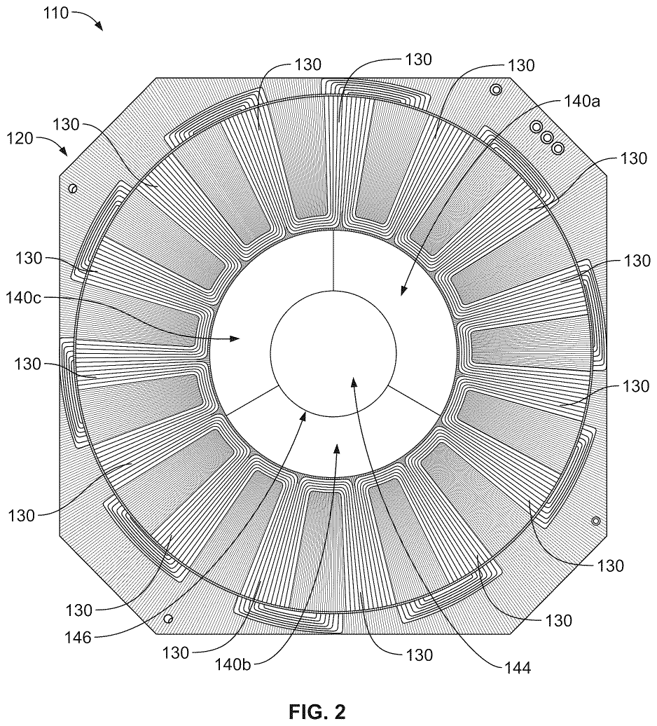

The present disclosure relates to printed circuit board stators with filter inductors, as described in detail below in connection with FIGS. 2-6.

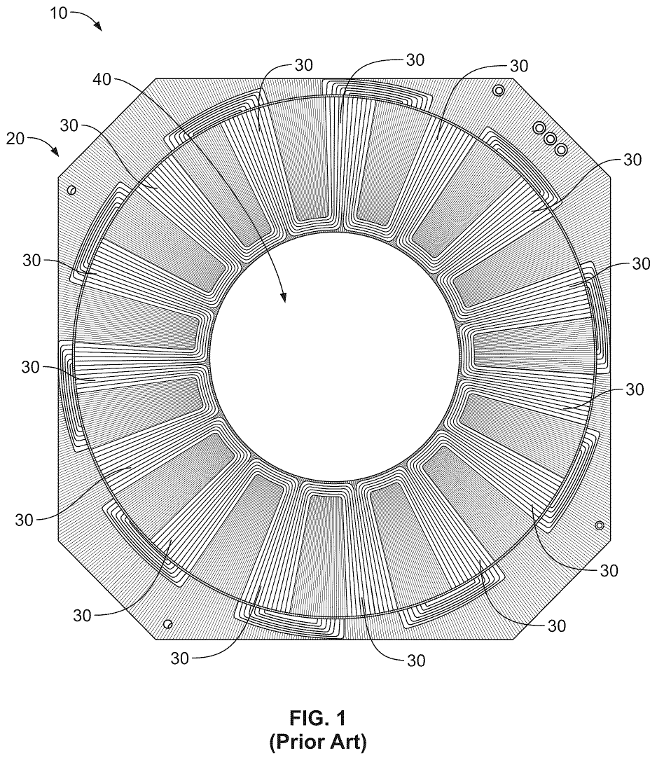

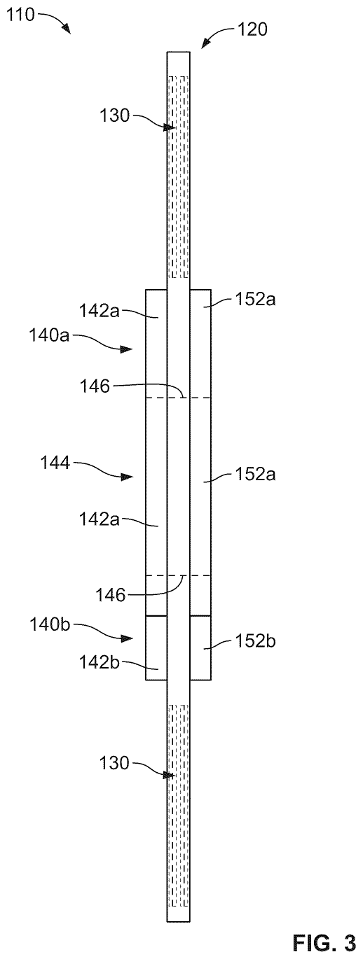

FIG. 2 is a diagram illustrating a PCB stator in accordance with the present disclosure, indicated generally at 110. The PCB stator 110 is an improvement upon the conventional PCB stator 10 shown in FIG. 1. The stator PCB 110 includes a multi-layer PCB 120, a plurality of stator coils 130 formed from interconnected copper traces on the layers of the PCB 120, a plurality of radially-positioned filter inductors 140a-140c, and a rotor shaft aperture 144 that extends through the PCB 120 and includes an annular inner wall 146 (see FIG. 3). The rotor shaft aperture 144 e has a diameter that is smaller than the diameter of the aperture 40 of the prior art PCB stator 10 shown in FIG. 1.

The filter inductors 140a-140c are generally arcuate and planar in shape, and are positioned circumferentially about the shaft aperture 144, extending radially outwardly from the shaft aperture 144. Of course, the filter inductors 140a-140c need not be planar or arcuate in shape, and could have other geometries and/or dimensions. The stator coils 130 are positioned circumferentially about and extend radially outwardly from the filter inductors 140a-140c. The filter inductors 140a-140c are in electrical communication with sets of the stator coils 130, and filter PWM drive signals that are transmitted to the inductors 140a-140c from a motor controller, such as a VFD motor controller. Each inductor 140a-140c could be in electrical communication with a specific drive phase of the VFD motor controller. For example, the first inductor 140a could be wired to a first phase of the VFD motor controller, the second inductor 140b could be wired to a second phase of the VFD motor controller, and the third inductor 140c could be wired to a third phase of the VFD motor controller. Advantageously, by positioning the inductors 140a-140c on the PCB stator 110 instead of in the VFD motor controller, the overall size of the VFD motor controller can be reduced.

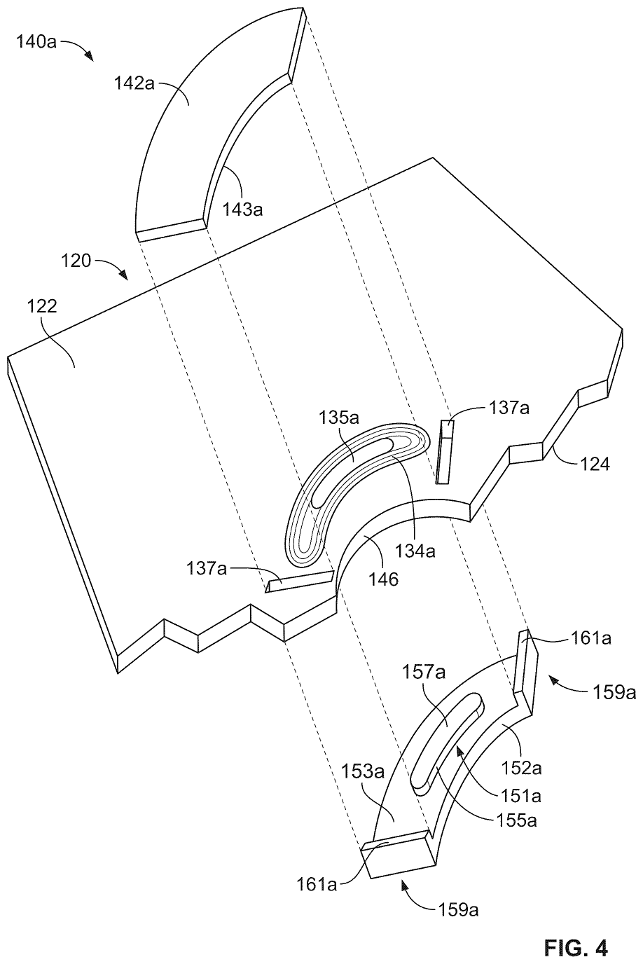

FIG. 3 is a side view of the PCB stator 110 of FIG. 2. The filter inductors 140a-140c include corresponding planar magnetic components 142a-142c (which could be formed from ferrite, powered iron where the energy is in the distributed gap, etc.) and 152a-152c (only components 142a-142b and 152a-152b are shown in the side view) which are positioned on opposite surfaces of the PCB 120, such that the planar magnetic components 142a-142c and 152a-152c “sandwich” the PCB 120 and corresponding filter inductor coils, discussed in more detail below in connection with FIG. 4. The stator coils 130 are formed by interconnected copper traces formed on layers of the PCB 120. It is noted that the filter inductors 140a-140c could be gapless laminated components, if desired.

FIG. 4 is an exploded partial perspective view of the PCB stator 120 of FIG. 2. As mentioned above, the inductors 140a-140c include respective pairs of planar magnetic components 142a-142c and 152a-152c positioned on opposite surfaces 122, 124 of the PCB 120, proximal to the annular inner wall 146, and each inductor 140a-140c includes a respective filter inductor coil. For illustration purposes, FIG. 4 shows the construction of only the first inductor 140a, but it should be understood that the second and third inductors 140b, 140c are identical in construction to the first inductor 140a. A filter inductor coil 134a is formed in the PCB 120 (in similar fashion as to how the stator coils 130 are formed, e.g., by interconnected copper traces formed on layers of the PCB 120), and a slot or aperture 135a is formed through the PCB 120 inside of the filter inductor coil 134a such that the filter inductor coil 134a surrounds the aperture 135a. Additionally, a pair of end slots or apertures 137a are formed through the PCB 120 near opposite ends of the filter inductor coil 134a. The filter inductor coil 134a is surrounded by the magnetic components 142a, 152a, such that the components 142a, 152a are mounted to opposite surfaces 122, 124 of the PCB 120 with the filter inductor coil 134a positioned therebetween forming the complete inductor 140a.

The magnetic component 152a includes a protrusion 151a extending from an upper surface 153a of the component 152a, which is generally sized and shaped to extend through the aperture 135a of the PCB 120 when the component 152a is positioned against the surface 124 of the PCB 120. The protrusion 151a is formed by an upright peripheral wall 155a and an upper wall 157a, such that the upper wall 157a contacts and abuts a lower surface 143a of the magnetic component 142a when the magnetic components 142a, 152a are positioned against the surfaces 122, 124 of the PCB 20. Additionally, the magnetic component 152a includes a pair of upwardly-extending walls 159a having top walls 161a. The upwardly-extending walls 159a extend through the apertures 137a and the top walls 161a contact (and abut) the lower surface 143a of the magnetic component 142a when the magnetic components 142a, 152a are positioned against the surfaces 122, 124 of the PCB 120. The abutment of the protrusion 151a, as well as the top walls 161a, against the lower surface 143a of the magnetic component 142a forms a complete magnetic circuit for the filter inductor coil 134a. Since magnetic pathing is a function of cross-sectional area, to maintain a roughly constant flux density, the surface area of the upper wall 157a is substantially equal to the combined surface areas of the top walls 161a. As a result, the protrusion 151a captures the magnetic flux of the filter inductor coil 134a and splits the magnetic pathing between the upwardly-extending walls 159a.

The planar magnetic components 142a, 152a could be mounted to the PCB 120 using clips that extend through corresponding apertures or slots in the PCB 120 so as to clamp the components 142a, 152a together with the coil 134a sandwiched between the components 142a, 152a. Alternatively, the planar magnetic components 142a, 152a could be attached to the opposite surfaces 122, 124 of the PCB 120 using other suitable attachment means, such as by gluing, screws, fasteners, varnish, tape, epoxy, or other type of attachment. Of course, the positioning and shapes of the planar magnetic components 142a, 152a as well as the filter inductor coil 134a and the apertures 135a and 137a need not be as shown in FIG. 4 and could have different shapes, e.g., they could be generally rectangular in shape, square in shape, circular in shape, or any other desired shape.

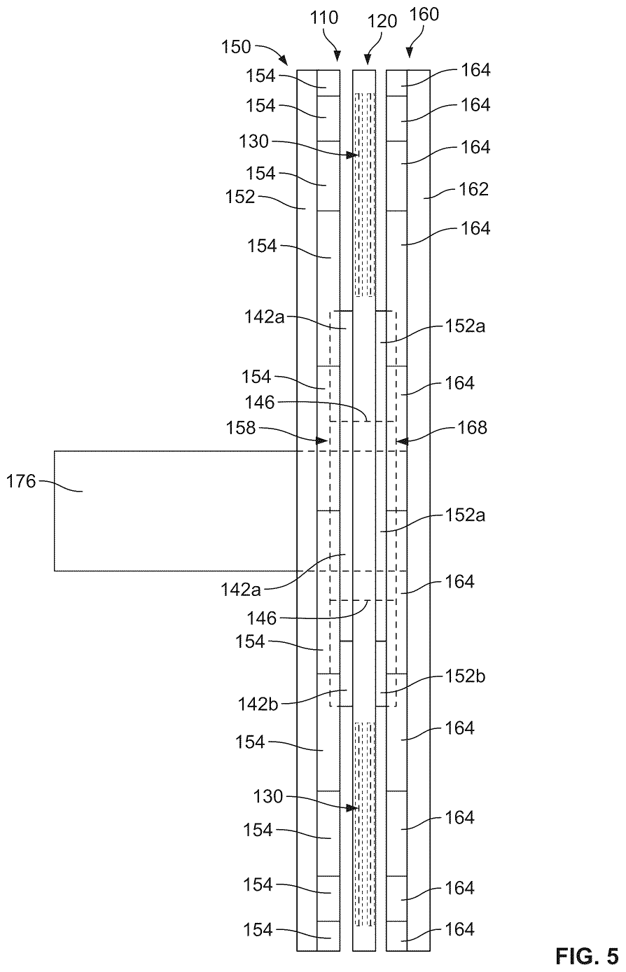

FIG. 5 is a side view of the PCB stator 110 of the present disclosure configured for operation with two planar rotors 150, 160 and an associated rotor shaft 176. The first rotor 150 includes a planar, generally circular rotor plate 152 to which a plurality of magnets 154 are attached on one side of the plate 152, extending radially outwardly. Similarly, the second rotor 160 includes a planar, generally circular rotor plate 162 to which a plurality of magnets 154 are attached on one side of the plate 162, extending radially outwardly. The plates 152 and 162 are mechanically coupled together by the shaft 176, such that when the plates 152 and 162 rotate together, they cause rotation of the shaft 176. The PCB stator 110 is fixed in space (e.g., by mounting of the stator 110 to a housing of a motor, for example), the shaft 176 extends through the shaft aperture 144, and the rotor plates 152, 162 rotate freely with respect to the stator 110. The magnets 154, 164 are positioned on opposite sides of the PCB stator 110 and generally align with the coils 130. When electrical current filtered by the inductors 140a-140c is supplied to the stator coils 130, an alternating magnetic field is established that attracts and repels the magnets 154, 164, causing rotation of the plates 152, 162 and thus rotation of the shaft 176 (which is mechanically coupled to the plates 152, 162), e.g., as the magnets 154, 164 are alternatively drawn to and repelled from the alternating magnetic fields.

The magnets 154, 164 extend outwardly from the plates 152, 162, and together with the plates 152, 162, define cavities 158, 168 that partially receive the magnetic structures 142a-142c and 152a-152c of the filter inductors 140a-140c, such that the magnetic structures 142a-142c and 152a-152c are partially “nested” within the magnets 154, 164, as illustrated by the dashed lines in FIG. 4. Advantageously, the cavities 158, 168 defined by the magnets 154, 164 and the plates 152, 162, which would ordinarily be wasted space in a conventional motor having a PCB stator, are instead occupied by the filter inductors 140a-140c. Alternatively, the plates 152, 162 could be etched, milled, molded, or otherwise fabricated so that they include recesses which accommodate the magnetic structures 142a-142c and 152a-152c.

The filter inductors 140a-140c create higher-order inductance which compensates for the lower-order inductances of the stator coils 130, allowing for slower switching speeds for the motor control (e.g., for the VFD circuit) and for higher voltages to be applied to a motor. Additionally, the planar filter inductors 140a-140c augment phase inductance and minimize electromagnetic interference (EMI) generated by the VFD, which also serves to improve the efficiency of the VFD. Further, by positioning the planar filter inductors 140a-140c off of the VFD circuit board(s), the overall cost and size of the VFD can be reduced. It is noted that the number of turns for the filter inductor coil 134a can vary depending on the required inductance value, and a single or even a fractional turn can be provided so as to concentrate the magnetic energy into a gap or a distributed gap.

Since the PCB 120 of the PCB stator 110 is used to form part of the filter inductors 140a-140c, decreases in raw materials, assembly sizes, and overall system costs are further advantages provided by the apparatus of the present disclosure. It is noted that the magnetic equation for inductor design, BsnAₑ>LIₚ, can be used to determine parameters for the filter inductors 140a-140c, wherein it is assumed that ferrite material Bs≈300 mT and Ip is defined by the system parameters, leaving only the turns, n, the effective cross sectional magnetic area, and the inductance. These parameters then allow for flexibility in choosing between planar transformer core shapes, PCB track width turns, widths, and stackups for a given PCB motor stator and VFD switching speed and/or drive voltage.

It is also noted that it is possible to mount additional electrical components to the PCB stator 110, using through-hole or surface-mounting techniques. Additionally, discrete inductor components can be embedded into components of the PCB stator 110, such as into the PCB 120. Moreover, since the inductors 140a-140c split the overall inductance supplied to the stator coils 130 over smaller sections, voltage distribution across the stator coils 130 (and hence, a motor in which the PCB stator 110 is utilized) is improved. This allows for inter-turn series components to be incorporated into the PCB stator 110, if desired. Also, if desired, the coils 130 could be split to insert a series inductance.

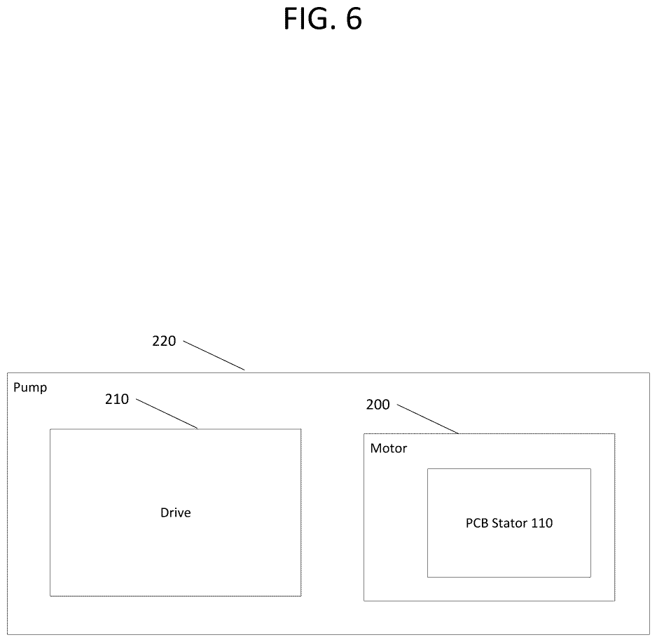

It is noted that the PCB stator 110 of the present disclosure could be utilized in connection with a wide variety of components, such as electronically-commutated motors, axial flux motors, variable speed motors, and other types of motors. Such motors incorporating the PCB stator 110 could be utilized in connection with a wide variety of applications, including, but not limited to, variable speed pool and spa pumps, booster pumps, and other types of pool/spa applications, as well as in other industries. For example, as shown in FIG. 6, the PCB stator 110 discussed herein (including the PCB, the stator coils, and the filter inductors) could be mounted in a motor assembly 200 which, as discussed above, could be an electronically-commutated motor, an axial flux motor, a variable speed motor, a single speed motor, etc.). The motor 200 could be in electrical communication with, and receive PWM drive signals from, a motor drive circuit 210 (which PWM signals could be filtered by the inductors of the PCB stator 110 as discussed above). The motor 200 and the drive circuit 210 could form part of a pump 220, such as a variable speed pool/spa pump.

Having thus described the systems and methods in detail, it is to be understood that the foregoing description is not intended to limit the spirit or scope thereof. It will be understood that the embodiments of the present disclosure described herein are merely exemplary and that a person skilled in the art can make any variations and modification without departing from the spirit and scope of the disclosure. All such variations and modifications, including those discussed above, are intended to be included within the scope of the disclosure. What is desired to be protected by Letters Patent is set forth in the following claims.

What is claimed is:

1. In a printed circuit board (PCB) stator having a PCB and a plurality of stator coils, the improvement comprising:
a plurality of filter inductors mounted to the PCB and in electrical communication with the plurality of stator coils,
the plurality of filter inductors positioned circumferentially about a rotor shaft aperture formed in the PCB and extending radially from the rotor shaft aperture, and the plurality of stator coils positioned circumferentially about and extending radially outwardly from the plurality of filter inductors.

2. The improvement of claim 1, wherein each of the plurality of filter inductors comprises a filter coil formed in the PCB.

3. The improvement of claim 2, wherein the filter coil is formed by interconnected copper traces formed on at least one layer of the PCB.

4. The improvement of claim 1, wherein each of the plurality of filter inductors comprises first and second planar magnetic components.

5. The improvement of claim 4, wherein the first and second planar magnetic components comprise ferrite or powdered iron components.

6. The improvement of claim 4, wherein the first planar magnetic component is mounted to a first side of the PCB and the second planar magnetic component is mounted to a second side of the PCB opposite the first side of the PCB.

7. The improvement of claim 6, wherein the first planar magnetic component includes a protrusion formed by an upright peripheral wall and an upper wall.

8. The improvement of claim 7, wherein the protrusion extends through an aperture formed in the PCB.

9. The improvement of claim 8, wherein the upright wall contacts and abuts a lower surface of the second planar magnetic component when the first and second planar magnetic components are positioned against the PCB.

10. The improvement of claim 6, wherein the first planar magnetic component includes a pair of upwardly-extending walls each having a top wall.

11. The improvement of claim 10, wherein the pair of upwardly-extending walls extends through apertures formed in the PCB.

12. The improvement of claim 11, wherein the top walls of the pair of upwardly-extending walls contacts and abuts a lower surface of the second planar magnetic component when the first and second planar magnetic components are positioned against the PCB.

13. The improvement of claim 1, wherein each of the plurality of filter inductors is generally planar and arcuate in shape.

14. The improvement of claim 1, wherein the plurality of filter inductors filter pulse-width modulated (PWM) drive signals transmitted to the plurality of inductors.

15. The improvement of claim 1, wherein the plurality of stator coils cause rotation of at least one rotor plate positioned proximal to the stator coils, the at least one rotor coupled to a rotor shaft extending through the rotor shaft aperture of the PCB.

16. The improvement of claim 15, wherein the at least one rotor plate includes a plurality of magnets, the plurality of stator coils establishing an alternating magnetic field that attracts and repels the plurality of magnets to cause rotation of the at least one rotor plate and the rotor shaft.

17. The improvement of claim 16, wherein at least one rotor plate and the plurality of magnets define a cavity that at least partially receives the plurality of filter inductors.

18. The improvement of claim 17, wherein the plurality of filter inductors are at least partially nested within the plurality of magnets.

19. The improvement of claim 1, wherein the plurality of filter inductors create high-order inductance that compensates for low-order inductances of the plurality of stator coils.

20. The improvement of claim 1, wherein the plurality of filter inductors augment phase inductance and reduce electromagnetic interference generated by a variable frequency drive in communication with the plurality of stator coils.

21. The improvement of claim 1, further comprising an electrical motor including the PCB, the plurality of stator coils, and the plurality of filter inductors.

22. The improvement of claim 21, further comprising a pump including the electrical motor.
